(19) United States
(12) Patent Application Publication
(10) Pub. No.: US 2026/0114161 A1
(43) Pub. Date: Apr. 23, 2026

(54) DISPLAY DEVICE AND ELECTRONIC DEVICE INCLUDING THE SAME

(71) Applicant: Samsung Display Co., Ltd., Yongin-si (KR)

(72) Inventors: Jeong Wan HAN, Yongin-si (KR); Hyun Cheol KIM, Yongin-si (KR); Hyeong Gyu KIM, Yongin-si (KR); Jae Hun SEO, Yongin-si (KR); Sang Ho LEE, Yongin-si (KR)

(21) Appl. No.: 19/292,660

(22) Filed: Aug. 6, 2025

(30) Foreign Application Priority Data
Oct. 22, 2024 (KR) 10-2024-0144535

(51) Int. Cl. H10K 59/80; H10K 59/122

(52) U.S. Cl. CPC H10K 59/878; H10K 59/122; H10K 59/879

(57) ABSTRACT

A display device includes: a substrate including a display area including a light emitting area and a non-light emitting area and a non-display area surrounding the display area; a light emitting element on the light emitting area; a side passivation layer on the light emitting element in a direction toward the non-light emitting area; a side reflective metal on the side passivation layer in a direction toward the non-light emitting area; a pixel defining layer on the non-light emitting area and defining an opening; a micro lens on the light emitting element; and a support metal on the non-display area and surrounding the display area, wherein the support metal overlaps the side passivation layer and the side reflective metal in a direction parallel to the substrate, and the pixel defining layer is in contact with and covers the side passivation layer, the side reflective metal, and the support metal.

### CROSS-REFERENCE TO RELATED APPLICATION

The present application claims priority to and the benefit of Korean Patent Application No. 10-2024-0144535, filed on Oct. 22, 2024, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

As an information society develops, consumer demand for a display device for displaying an image is increasing in various forms. For example, display devices may be applied to various electronic devices such as smartphones, digital cameras, laptop computers, navigation devices, and smart televisions. The display devices may be flat panel display devices such as liquid crystal display devices, field emission display devices, or organic light emitting display devices. Among the flat panel display devices, the light emitting display device may include a light emitting element in which each of the pixels of a display panel may emit light by itself, thereby displaying an image without a backlight unit providing the light to the display panel.

For example, display devices may be applied to glasses-type devices to provide virtual reality and augmented reality. In order for the display device to be applied to the glasses-type device, the display device may desirably be implemented in a very small size of two inches or less, but may desirably have a high pixel integration in order to be implemented with high resolution. For example, the display device may have a high pixel integration of 1000 pixels per inch (PPI) or more.

As described above, when the display device is implemented in a very small size but has high pixel integration, it may be difficult to implement light emitting elements separated for each light emitting area using a mask process because an area of a light emitting area where the light emitting elements are located is relatively reduced.

The above information disclosed in this Background section is only for enhancement of understanding of the background and therefore the information discussed in this Background section does not necessarily constitute prior art.

### SUMMARY

Aspects of some embodiments of the present disclosure may relatively improve optical efficiency and reliability of a display device applicable to ultra-high resolution products.

However, aspects of embodiments of the present disclosure are not restricted to those set forth herein. The above and other aspects of the present disclosure will become more apparent to one of ordinary skill in the art to which the present disclosure pertains by referencing the detailed description of embodiments according to the present disclosure given below.

Details of other embodiments are included in the detailed description and drawings.

According to some embodiments of the present disclosure, a display device includes a substrate including a display area including a light emitting area and a non-light emitting area and a non-display area surrounding the display area; a light emitting element positioned on the light emitting area of the substrate; a side passivation layer positioned on the light emitting element in a direction toward the non-light emitting area; a side reflective metal positioned on the side passivation layer in a direction toward the non-light emitting area; a pixel defining layer positioned on the non-light emitting area of the substrate and defining an opening; a micro lens positioned on the light emitting element; and a support metal positioned on the non-display area of the substrate and positioned to surround the display area, wherein the support metal is positioned to overlap the side passivation layer and the side reflective metal in a direction parallel to the substrate, and the pixel defining layer is in contact with and covers the side passivation layer, the side reflective metal, and the support metal.

According to some embodiments, the side passivation layer and the side reflective metal may overlap the light emitting area, and may do not overlap the opening.

According to some embodiments, the support metal may do not overlap the display area, and the support metal is positioned to overlap the light emitting element in the direction parallel to the substrate.

According to some embodiments, the support metal may include: a first layer facing the display area; a second layer positioned on the first layer toward the outermost portion of the substrate and including a material different from that of the first layer; and a third layer positioned on the second layer toward the outermost portion of the substrate and including the same material as the first layer.

According to some embodiments, the first layer and the third layer of the support metal may include either titanium nitride or tungsten nitride, and the second layer includes either titanium or tungsten.

According to some embodiments, the side passivation layer may include a first layer in contact with the light emitting element; a second layer positioned on the first layer and including a material different from that of the first layer; and a third layer positioned on the second layer and in contact with the side reflective metal.

According to some embodiments, the light emitting element includes an anode electrode, a light emitting layer, and a cathode electrode, and the first layer is in contact with and covers a side surface of the anode electrode and a side surface of the light emitting layer facing the non-light emitting area.

According to some embodiments, the first layer is not in contact with an upper surface of the light emitting layer facing the cathode electrode.

According to some embodiments, the light emitting element further includes a connection electrode positioned toward the substrate and a reflective electrode positioned between the connection electrode and the anode electrode, and the first layer is in contact with and covers a side surface of the connection electrode and a side surface of the reflective electrode facing the non-light emitting area.

According to some embodiments, the side passivation layer and the side reflective metal are spaced apart from each other with the cathode electrode and the pixel defining layer interposed therebetween in a direction perpendicular to the substrate.

According to some embodiments, in a plan view, the side passivation layer completely surrounds the light emitting layer, and in the plan view, the side reflective layer completely surrounds the side passivation layer.

According to some embodiments, the display device may further comprise a passivation layer positioned on the pixel defining layer in a portion overlapping the light emitting area and the non-light emitting area; and a lens passivation layer positioned on the micro lens.

According to some embodiments, the passivation layer may include a first layer in contact with the light emitting element; a second layer positioned on the first layer and including a material different from that of the first layer; and a third layer positioned on the second layer, in contact with the micro lens, and including the same material as the first layer.

According to some embodiments, the first layer, the second layer and the third layer of the passivation layer may overlap the side passivation layer and the side reflective metal in a direction perpendicular to the substrate.

According to some embodiments, the micro lens is positioned to be in contact between the passivation layer and the lens passivation layer, and the passivation layer and the lens passivation layer are in contact with each other in a portion that does not overlap the micro lens.

According to some embodiments, the lens passivation layer may include a first layer in contact with the micro lens; a second layer positioned on the first layer and including a material different from that of the first layer; and a third layer positioned on the second layer and including the same material as the first layer.

According to some embodiments, the first layer, the second layer and the third layer of the lens passivation layer may overlap the side passivation layer and the side reflective metal in a direction perpendicular to the substrate.

According to some embodiments of the present disclosure, an electronic device comprising at least one display device which comprises a substrate comprising a display area including a light emitting area and a non-light emitting area and a non-display area surrounding the display area; a light emitting element positioned on the light emitting area of the substrate; a side passivation layer positioned on the light emitting element in a direction toward the non-light emitting area; a side reflective metal positioned on the side passivation layer in a direction toward the non-light emitting area; a pixel defining layer positioned on the non-light emitting area of the substrate and defining an opening; a micro lens positioned on the light emitting element; and a support metal positioned on the non-display area of the substrate and positioned to surround the display area, wherein the support metal is positioned to overlap the side passivation layer and the side reflective metal in a direction parallel to the substrate, and the pixel defining layer is in contact with and covers the side passivation layer, the side reflective metal, and the support metal.

The display device according to some embodiments may prevent or reduce permeation of contaminants such as oxygen or moisture by including the protective layer covering the side and upper surfaces of the light emitting element and the upper surface of the micro lens, thereby relatively improving reliability of the display device.

Furthermore, the display device according to some embodiments may relatively improve light efficiency by including the reflective electrode covering the side surface of the light emitting element, thereby relatively improving the reliability of the display device.

In addition, the display device according to some embodiments may protect pixels from physical shock caused during the manufacturing process by including the support metal surrounding the display area, thereby relatively improving the reliability of the display device.

However, the characteristics of embodiments according to the present disclosure are not restricted to those specifically set forth herein. The above and other characteristics of some embodiments will become more apparent to one of ordinary skill in the art to which the disclosed embodiments pertain by referencing the claims, and their equivalents.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a head mounted electronic device according to some embodiments;

FIG. 2 is an exploded perspective view illustrating of the head mounted electronic device of FIG. 1;

FIG. 3 is a perspective view illustrating a head mounted electronic device according to some embodiments;

FIG. 4 is an exploded perspective view illustrating a display device according to some embodiments;

FIG. 5 is a plan view of a display panel of FIG. 4;

FIG. 6 is a plan view illustrating an arrangement of light emitting areas in a display area of FIG. 5;

FIG. 7 is a schematic cross-sectional view of the display panel taken along the line D-D′ in FIG. 6;

FIG. 8 is an enlarged cross-sectional view of a light emitting element layer and an optical layer positioned to overlap a first light emitting area in FIG. 7;

FIG. 9 is an enlarged cross-sectional view of area A of FIG. 8;

FIG. 10 is a plan view illustrating an arrangement of a first light emitting layer, a side passivation layer, and a side reflective metal in FIG. 9;

FIG. 11 is a schematic cross-sectional view of the display panel taken along the line D-D′ in FIG. 6 according to some embodiments;

FIG. 12 is a graph comparing reflectance of the display panel of FIG. 7 and the display panel of FIG. 11; and

FIG. 13 is a schematic cross-sectional view of the display panel taken along the line N-N′ in FIG. 5.

FIG. 14 is a block diagram of an electronic device according to one embodiment of the present disclosure.

FIG. 15 is a schematic diagram of an electronic device according to various embodiments of the present disclosure.

### DETAILED DESCRIPTION

The present invention will now be described more fully herein with reference to the accompanying drawings, in which some embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the invention. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, aspects of some embodiments of the present disclosure will be described in more detail with reference to the accompanying drawings.

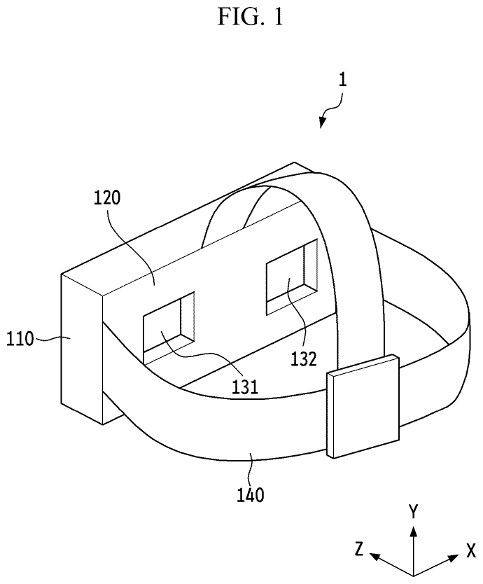

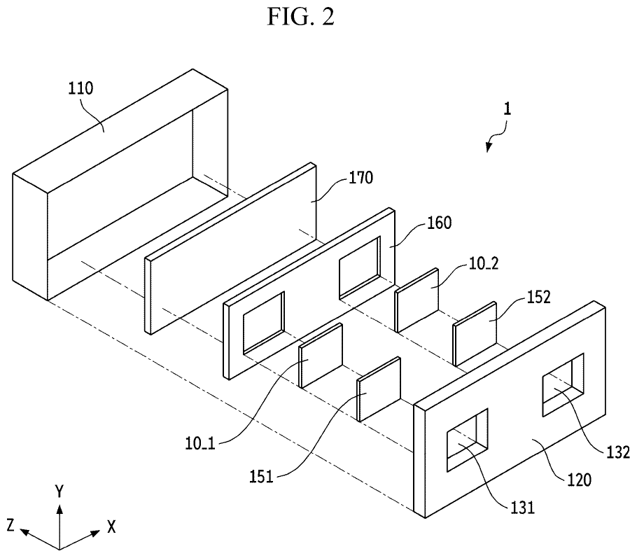

FIG. 1 is a perspective view illustrating a head mounted electronic device according to some embodiments. FIG. 2 is an exploded perspective view illustrating of the head mounted electronic device of FIG. 1.

Referring to FIGS. 1 and 2, a head mounted electronic device 1 according to some embodiments may include a display device 10, a display device accommodating portion 110, an accommodating portion cover 120, a first eyepiece 131, a second eyepiece 132, a head mounting band 140, a middle frame 160, a first optical member 151, a second optical member 152, and a control circuit board 170.

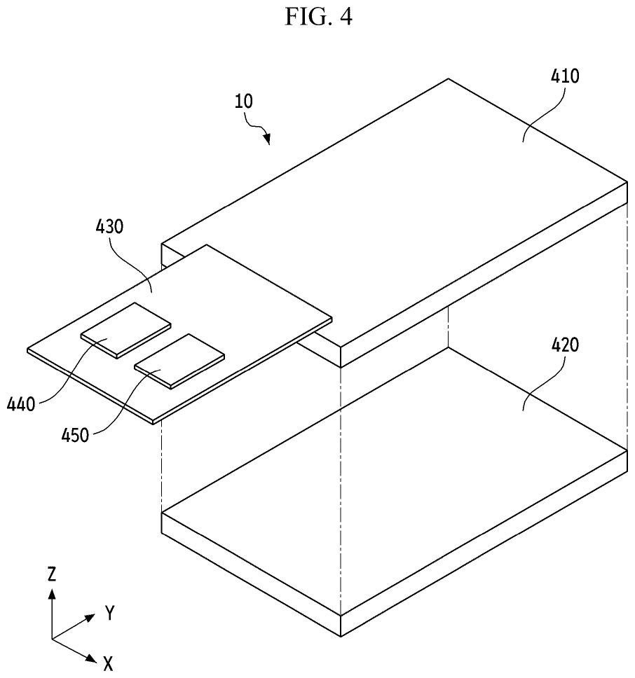

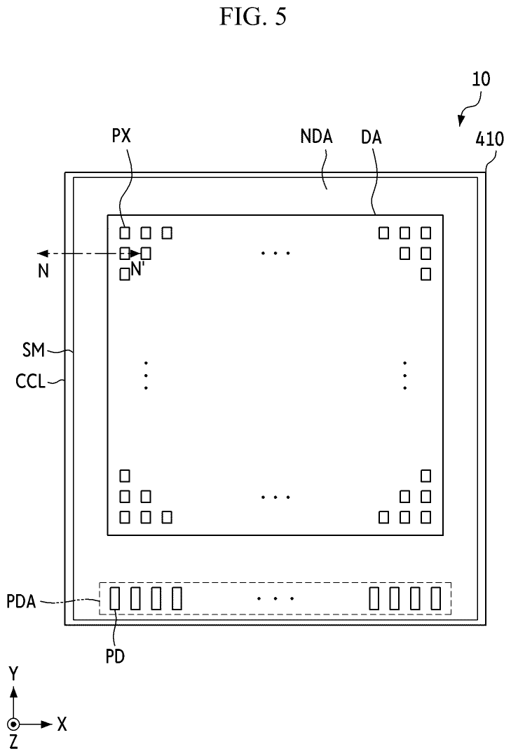

The display device 10 may include a first display device 10_1 and a second display device 10_2. The first display device 10_1 provides images to a user's left eye, and the second display device 10_2 provides images to a user's right eye. A detailed description of the display device 10 will be described in more detail later with reference to FIGS. 4 and 5.

The first optical member 151 may be positioned between the first display device 10_1 and the first eyepiece 131, and the second optical member 152 may be positioned between the second display device 10_2 and the second eyepiece 132. Each of the first optical member 151 and the second optical member 152 may include at least one convex lens.

The middle frame 160 may be located between the first display device 10_1 and the control circuit board 170 and may be positioned between the second display device 10_2 and the control circuit board 170. The middle frame 160 serves to support and fix the first display device 10_1, the second display device 10_2, and the control circuit board 170.

The control circuit board 170 may be positioned between the middle frame 160 and the display device accommodating portion 110. The control circuit board 170 may be connected to the first display device 10_1 and the second display device 10_2 through a connector. The control circuit board 170 may convert an image source input from the outside into digital video data, and may transmit the digital video data to the first display device 10_1 and the second display device 10_2 through the connector.

The control circuit board 170 may transmit digital video data corresponding to a left eye image optimized for the user's left eye to the first display device 10_1, and may transmit digital video data corresponding to a right eye image optimized for the user's right eye to the second display device 10_2. Alternatively, the control circuit board 170 may transmit the same digital video data to the first display device 10_1 and the second display device 10_2.

The display device accommodating portion 110 serves to accommodate the display device 10, the middle frame 160, the first optical member 151, the second optical member 152, and the control circuit board 170. The accommodating portion cover 120 is arranged to cover one opened surface of the display device accommodating portion 110. The accommodating portion cover 120 may include a first eyepiece 131 where the user's left eye is located and a second eyepiece 132 where the user's right eye is located. It is illustrated in FIGS. 1 and 2 that the first eyepiece 131 and the second eyepiece 132 are separately arranged, but the embodiments of the present disclosure are not limited thereto. The first eyepiece 131 and the second eyepiece 132 may be integrated into one.

The first eyepiece 131 may be aligned with the first display device 10_1 and the first optical member 151, and the second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

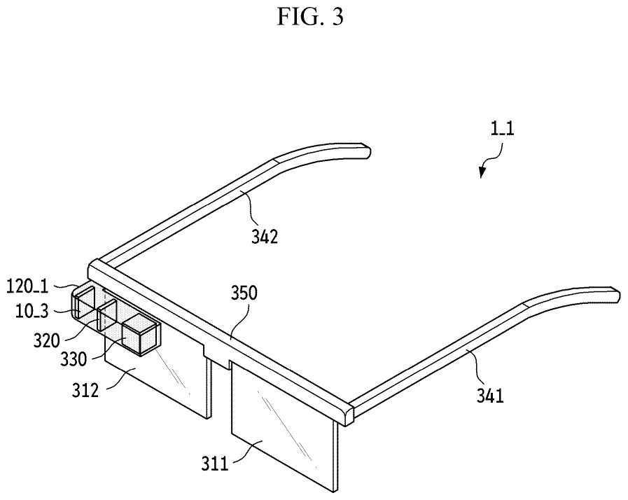

The head mounting band 140 serves to fix the display device accommodating portion 110 to a user's head so that the first eyepiece 131 and the second eyepiece 132 of the accommodating portion cover 120 are located on the user's left and right eyes, respectively. When the display device accommodating portion 110 is implemented in a lightweight and small size, the head mounted electronic device 1 may include eyeglass frames as illustrated in FIG. 3 instead of the head mounting band 140.

In addition, the head mounted electronic device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view illustrating a head mounted electronic device according to some embodiments.

Referring to FIG. 3, a head mounted electronic device 1_1 according to some embodiments may be a glasses-type electronic device in which a display device accommodating portion 120_1 is implemented in a lightweight and small size. The head mounted electronic device 1_1 according to some embodiments may include a display device 10, a left eye lens 311, a right eye lens 312, a support frame 350, eyeglass frame legs 341 and 342, an optical member 320, a light path conversion member 330, and a display device accommodating portion 120_1.

The display device 10 illustrated in FIG. 3 may include a third display device 10_3. The third display device 10_3 may be the same (or substantially the same) as the first display device 10_1 and the second display device 10_2 illustrated in FIG. 2. The display device 10 will be described later with reference to FIGS. 4 and 5.

The display device accommodating portion 120_1 may include the display device 10, the optical member 320, and the light path conversion member 330. As an image displayed on the display device 10 is magnified by the optical member 320 and a light path thereof is converted by the light path conversion member 330, the image may be provided to the user's right eye through the right eye lens 312.

Accordingly, the user may view an augmented reality image in which a virtual image displayed on the display device 10 and a real image viewed through the right eye lens 312 are combined through the right eye.

It is illustrated in FIG. 3 that the display device accommodating portion 120_1 is located at a right distal end of the support frame 350, but the embodiments of the present disclosure are not limited thereto. For example, the display device accommodating portion 120_1 may be positioned at a left distal end of the support frame 350, and in this case, the image of the display device 10 may be provided to the user's left eye. Alternatively, the display device accommodating portions 120_1 may be positioned at both the left and right distal ends of the support frame 350. In this case, the user may view the image displayed on the display device 10 through both the user's left and right eyes.

FIG. 4 is an exploded perspective view illustrating a display device 10 according to some embodiments.

Referring to FIG. 4, a display device 10 according to some embodiments is a device that displays a moving image or a still image. The display device 10 according to some embodiments may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 may be applied to a display unit of a television, a laptop computer, a monitor, a billboard, or the Internet of Things (IOT). Alternatively, the display device 10 may be applied to a smart watch, a watch phone, and a head mounted display (HMD) for implementing virtual reality and augmented reality.

The display device 10 according to some embodiments includes a display panel 410, a heat dissipation layer 420, a circuit board 430, a driving circuit 440, and a power supply circuit 450.

The display panel 410 may be formed in a planar shape similar to a quadrangle. For example, the display panel 410 may have a planar shape similar to a quadrangle having short sides in a first direction (X-axis direction) and long sides in a second direction (Y-axis direction) intersecting the first direction (X-axis direction). In the display panel 410, a corner where the short side in the first direction (X-axis direction) and the long side in the second direction (Y-axis direction) meet each other may be formed at a right angle or may be formed in a round shape so as to have a curvature (e.g., a set or predetermined curvature). The planar shape of the display panel 410 is not limited to the quadrangle, and may be formed similarly to other polygons, circles, or ovals. A planar shape of the display device 10 may follow the planar shape of the display panel 410, but the embodiments of the present disclosure are not limited thereto.

The heat dissipation layer 420 may overlap the display panel 410 in a third direction (Z-axis direction), which is a thickness direction of the display panel 410. The heat dissipation layer 420 may be positioned on one surface of the display panel 410, for example, a rear surface thereof. The heat dissipation layer 420 serves to dissipate heat generated from the display panel 410. The heat dissipation layer 420 may include a metal layer such as graphite, silver (Ag), copper (Cu), or aluminum (Al) having high thermal conductivity.

The circuit board 430 may be positioned on the non-display area NDA of the display panel 410 using a conductive adhesive material such as an anisotropic conductive film. The circuit board 430 may be a flexible printed circuit board or flexible film made of a flexible material. It is illustrated in FIG. 4 that the circuit board 430 is unfolded, but the circuit board 430 may be bent. In this case, one end of the circuit board 430 may be positioned on the rear surface of the display panel 410.

One end of the circuit board 430 may be an opposite end of the other end of the circuit board 430 connected to a plurality of pads of the pad area of the display panel 410 by using a conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate a plurality of panel driving voltages according to a power voltage from the outside. For example, the power supply circuit 450 may generate a first driving voltage (e.g., VSS), a second driving voltage (e.g., VDD), and a third driving voltage (e.g., VINT) and supply the generated driving voltages to the display panel 410.

The driving circuit 440 and the power supply circuit 450 may be each formed as an integrated circuit (IC) and attached to one surface of the circuit board 430.

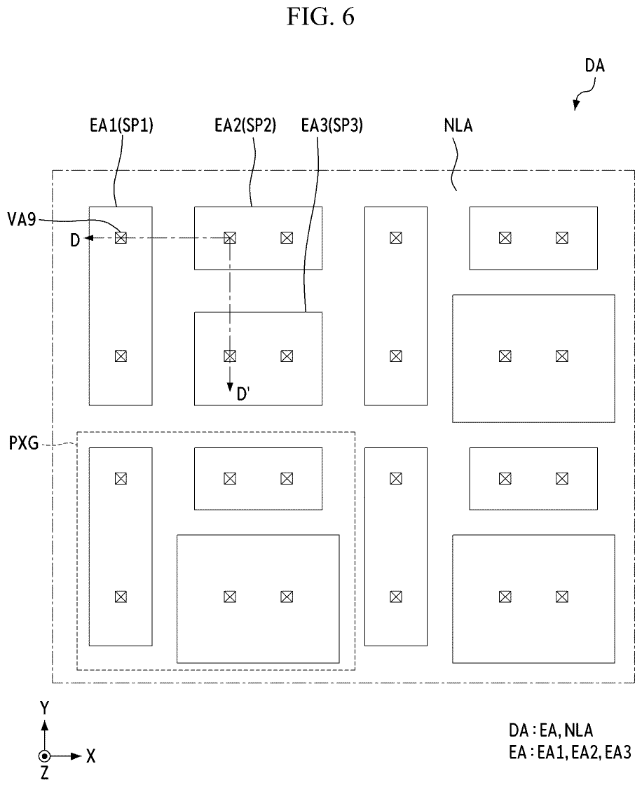

FIG. 5 is a plan view of the display panel of FIG. 4, and FIG. 6 is a plan view illustrating an arrangement of light emitting areas in a display area of FIG. 5.

Referring to FIGS. 5 and 6, the display panel 410 according to some embodiments may include a display area DA, a non-display area NDA, and a pad area PDA.

The display area DA may be positioned at the center of the display panel 410 and may occupy most of the area of the display panel 410. The display area DA may include a light emitting area EA and a non-light emitting area NLA. The light emitting area EA may be a portion that emits light, and the non-light emitting area NLA may be a portion that assists in preventing or reducing mixing of the light emitted from each light emitting area EA.

The display area DA may include a plurality of pixel groups PXG. Each pixel group PXG may be separated from each other. The pixel group PXG may be a minimum unit that emits white light.

The pixel group PXG may include a first sub-pixel SP1, a second sub-pixel SP2, and a third sub-pixel SP3 that include different light emitting areas EA.

For example, the first sub-pixel SP1 may include a first light emitting area EA1, the second sub-pixel SP2 may include a second light emitting area EA2, and the third sub-pixel SP3 may include a third light emitting area EA3. It is illustrated in the drawing that the pixel group PXG includes the first to third sub-pixels SP1, SP2, and SP3, but the embodiments of the present disclosure are not limited thereto. According to some embodiments, the pixel group PXG may also include four different sub-pixels.

The first light emitting area EA1, the second light emitting area EA2, and third light emitting area EA3 may emit light of different colors. As an example, the first light emitting area EA1 emits light of a first color, the second light emitting area EA2 emits light of a second color, and the third light emitting area EA3 emits light of a third color. Here, the light of the first color may be light in a red wavelength band, the light of the second color may be light in a green wavelength band, and the light of the third color may be light in a blue wavelength band.

The first light emitting area EA1 and the second light emitting area EA2 may be adjacent in the first direction (X-axis direction), and the first light emitting area EA1 and the third light emitting area EA3 may be adjacent in the first direction (X-axis direction). In addition, the second light emitting area EA2 and the third light emitting area EA3 may be adjacent to each other in the second direction (Y-axis direction), but the embodiments of the present disclosure are not limited thereto.

The first light emitting area EA1, the second light emitting area EA2, and the third light emitting area EA3 may have a hexagonal planar shape formed of six straight lines, but the embodiments of the present disclosure are not limited thereto. The first light emitting area EA1, the second light emitting area EA2, and the third light emitting area EA3 have a planar shape other than the hexagon, such as a polygon, circle, ellipse, or irregular shape. An area of the first light emitting area EA1, an area of the second light emitting area EA2, and an area of the third light emitting area EA3 may be different.

Each of the first sub-pixel SP1, the second sub-pixel SP2, and the third sub-pixel SP3 may include a ninth via VA9 therein. Details will be described later.

The pad area PDA may be located on a lower side, which is one side of the display area DA in the second direction (Y-axis direction). A plurality of pads PD arranged in the first direction (X-axis direction) may be located in the pad area PDA. The circuit board (430 in FIG. 4) described in FIG. 4 may be attached onto the plurality of pads PD. The plurality of pads PD may be electrically connected to the circuit board 430.

The non-display area NDA may be positioned to surround the display area DA and the pad area PDA. The non-display area NDA may refer to an edge area of the display panel 410. A plurality of lines and a support metal SM that electrically connect the pad PD and the pixel PX may be positioned in a portion overlapping the non-display area NDA.

The support metal SM according to some embodiments may be positioned to surround an outer portion of the display area DA. In other words, the support metal SM may be positioned to surround the edge of the display panel 410.

The display device 10 according to some embodiments may be formed on a silicon wafer during a manufacturing process. The display device 10 may be formed in multiple pieces on the silicon wafer and then separated into the shape illustrated by a dicing process, which is a process of separating each display device 10. The dicing process may be performed by applying physical force along a cell cut line CCL, which is the outermost portion of the display panel 410.

The support metal SM may relatively reduce an impact applied to the plurality of pixels PX positioned in the display area DA when performing the dicing process. In addition, the support metal SM may protect the plurality of pixels PX positioned in the display area DA from moisture and oxygen permeating from the outside. The detailed structure of the support metal SM will be described later.

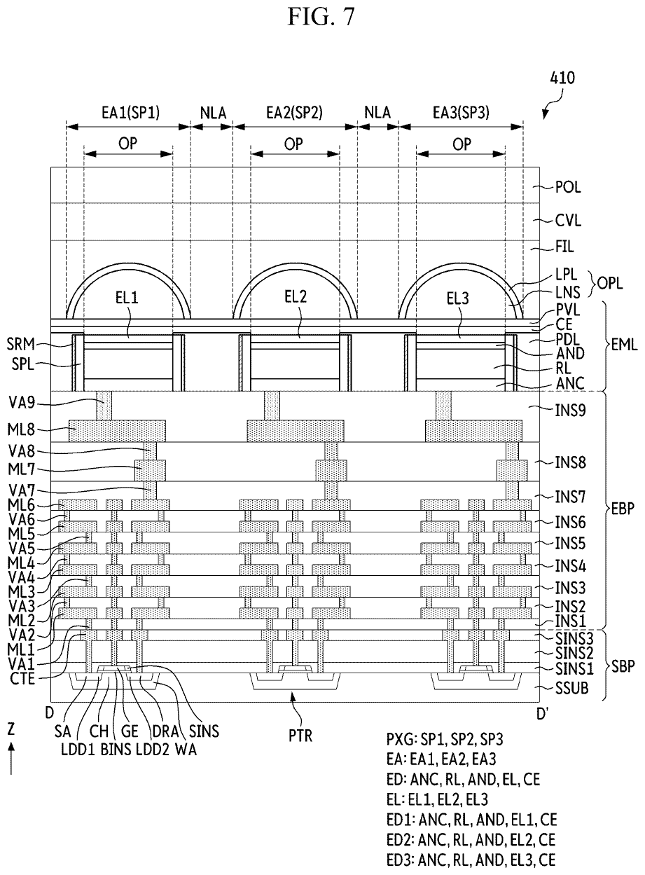

FIG. 7 is a schematic cross-sectional view of the display panel taken along the line D-D′ in FIG. 6.

Referring to FIG. 7, the display panel 410 includes a semiconductor backplane SBP, a light emitting element backplane EBP, a light emitting element layer EML, an optical layer OPL, a cover layer CVL, and an optical film POL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be positioned on an upper surface of the semiconductor substrate SSUB. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

The semiconductor substrate SSUB may be replaced with a glass substrate or a polymer resin substrate such as polyimide. In this case, thin film transistors may be positioned on the glass substrate or the polymer resin substrate. The glass substrate may be a rigid substrate that is not bent, and the polymer resin substrate may be a flexible substrate that may be bent or curved.

Each of the plurality of well areas WA includes a source area SA corresponding to a source electrode of the pixel transistor PTR, a drain area DRA corresponding to a drain electrode thereof, and a channel area CH located between the source area SA and the drain area DRA.

Each of the source area SA and the drain area DRA may be an area doped with first-type impurities. A gate electrode GE of the pixel transistor PTR may overlap the well area WA in the third direction (Z-axis direction). The channel area CH may overlap the gate electrode GE in the third direction (Z-axis direction). The source area SA may be located on one side of the gate electrode GE, and the drain area DRA may be located on the other side of the gate electrode GE.

A first semiconductor insulating film SINS1 may be positioned on the semiconductor substrate SSUB. The first semiconductor insulating film SINS1 may be formed as an inorganic film of silicon nitride carbon or silicon oxide series, but the embodiments of the present disclosure are not limited thereto.

A second semiconductor insulating film SINS2 may be positioned on the first semiconductor insulating film SINS1. The second semiconductor insulating film SINS2 may be formed as an inorganic film of silicon oxide series, but the embodiments of the present disclosure are not limited thereto.

A plurality of contact terminals CTE may be positioned on the second semiconductor insulating film SINS2. Each of the plurality of contact terminals CTE may be connected to at least one of the gate electrode GE, the source area SA, or the drain area DRA of each of the plurality of pixel transistors PTR through a hole penetrating through the first semiconductor insulating film SINS1 and the second semiconductor insulating film SINS2. The plurality of contact terminals CTE may be formed of at least one of copper (Cu), aluminum (Al), tungsten (W), molybdenum (Mo), chromium (Cr), gold (Au), titanium (Ti), nickel (Ni), or neodymium (Nd), or an alloy including any one thereof.

A third semiconductor insulating film SINS3 may be positioned on a side surface of each of the plurality of contact terminals CTE. An upper surface of each of the plurality of contact terminals CTE may be exposed without being covered by the third semiconductor insulating film SINS3. The third semiconductor insulating film SINS3 may be formed as an inorganic film of silicon oxide series, but the embodiments of the present disclosure are not limited thereto.

The light emitting element backplane EBP includes first to eighth metal layers ML1 to ML8, reflective metal layers RL1 to RL4, a plurality of vias VA1 to VA10, and a step layer STPL. In addition, the light emitting element backplane EBP includes a plurality of first to ninth interlayer insulating films INS1 to INS9 located between the first to sixth metal layers ML1 to ML6.

The first to eighth metal layers ML1 to ML8 serve to implement a circuit of a sub-pixel SP by connecting the plurality of contact terminals CTE exposed from the semiconductor backplane SBP.

The first interlayer insulating film INS1 may be positioned on the semiconductor backplane SBP. Each of the first vias VA1 may penetrate through the first interlayer insulating film INS1 and be connected to the contact terminal CTE exposed from the semiconductor backplane SBP. Each of the first layers ML1 may be located on the first interlayer insulating film INS1 and may be connected to the first via VA1.

The second interlayer insulating film INS2 may be positioned on the first interlayer insulating film INS1 and the first layers ML1. Each of the second vias VA2 may be connected to the first layer ML1 exposed by penetrating through the second interlayer insulating film INS2. Each of the second layers ML2 may be located on the second interlayer insulating film INS2 and may be connected to the second via VA2.

The third interlayer insulating film INS3 may be positioned on the second interlayer insulating film INS2 and the second layers ML2. Each of the third vias VA3 may be connected to the second layer ML2 exposed by penetrating through the third interlayer insulating film INS3. Each of the third layers ML3 may be located on the third interlayer insulating film INS3 and may be connected to the third via VA3.

The fourth interlayer insulating film INS4 may be positioned on the third interlayer insulating film INS3 and the third layers ML3. Each of the fourth vias VA4 may be connected to the third layer ML3 exposed by penetrating through the fourth interlayer insulating film INS4. Each of the fourth metal layers ML4 may be located on the fourth interlayer insulating film INS4 and may be connected to the fourth via VA4.

The fifth interlayer insulating film INS5 may be positioned on the fourth interlayer insulating film INS4 and the fourth metal layers ML4. Each of the fifth vias VA5 may be connected to the fourth metal layer ML4 exposed by penetrating through the fifth interlayer insulating film INS5. Each of the fifth metal layers ML5 may be located on the fifth interlayer insulating film INS5 and may be connected to the fifth via VA5.

The sixth interlayer insulating film INS6 may be positioned on the fifth interlayer insulating film INS5 and the fifth metal layers ML5. Each of the sixth vias VA6 may be connected to the fifth metal layer ML5 exposed by penetrating through the sixth interlayer insulating film INS6. Each of the sixth metal layers ML6 may be located on the sixth interlayer insulating film INS6 and may be connected to the sixth via VA6.

The seventh interlayer insulating film INS7 may be positioned on the sixth interlayer insulating film INS6 and the sixth metal layers ML6. Each of the seventh vias VA7 may be connected to the sixth metal layer ML6 exposed by penetrating through the seventh interlayer insulating film INS7. Each of the seventh metal layers ML7 may be located on the seventh interlayer insulating film INS7 and may be connected to the seventh via VA7.

The eighth interlayer insulating film INS8 may be positioned on the seventh interlayer insulating film INS7 and the seventh metal layers ML7. Each of the eighth vias VA8 may be connected to the seventh metal layer ML7 exposed by penetrating through the eighth interlayer insulating film INS8. Each of the eighth metal layers ML8 may be located on the eighth interlayer insulating film INS8 and may be connected to the eighth via VA8.

The first to eighth metal layers ML1 to ML8 and the first to eighth vias VA1 to VA8 may be formed of the same (or substantially the same) material. The first to eighth metal layers ML1 to ML8 and the first to eighth vias VA1 to VA8 may be formed of at least one of copper (Cu), aluminum (Al), tungsten (W), molybdenum (Mo), chromium (Cr), gold (Au), titanium (Ti), nickel (Ni), or neodymium (Nd), or an alloy including any one thereof. The first to eighth vias VA1 to VA8 may be formed of the same (or substantially the same) material. The first to eighth interlayer insulating films INS1 to INS8 may be formed as an inorganic film of silicon oxide series, but the embodiments of the present disclosure are not limited thereto.

A thickness of the first layer ML1, a thickness of the second layer ML2, a thickness of the metal layer ML3, a thickness of the fourth metal layer ML4, a thickness of the fifth metal layer ML5, and a thickness of the sixth metal layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second layer ML2, the thickness of the metal layer ML3, the thickness of the fourth metal layer ML4, the thickness of the fifth metal layer ML5, and the thickness of the sixth metal layer ML6 may be greater than the thickness of the first layer ML1. The thickness of the second layer ML2, the thickness of the metal layer ML3, the thickness of the fourth metal layer ML4, the thickness of the fifth metal layer ML5, and the thickness of the sixth metal layer ML6 may be the same (or substantially the same).

Each of a thickness of the seventh metal layer ML7 and a thickness of the eighth metal layer ML8 may be greater than each of the thickness of the first layer ML1, the thickness of the second layer ML2, the thickness of the third layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8.

Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be the same (or substantially the same).

A ninth interlayer insulating film INS9 may be positioned on the eighth interlayer insulating film INS8 and the eighth metal layers ML8. The ninth interlayer insulating film INS9 may be formed as an inorganic film silicon oxide series, but the embodiments of the present disclosure are not limited thereto.

Each of the ninth vias VA9 may be connected to the eighth metal layer ML8 exposed by penetrating through the ninth interlayer insulating film INS9. The ninth vias VA9 may be formed of at least one of copper (Cu), aluminum (Al), tungsten (W), molybdenum (Mo), chromium (Cr), gold (Au), titanium (Ti), nickel (Ni), or neodymium (Nd), or an alloy including any one thereof.

The light emitting element layer EML may be positioned on the light emitting element backplane EBP. The light emitting element layer EML may include a light emitting element ED, a side passivation layer SPL, a side reflective metal SRM, and a passivation layer PVL.

The light emitting element ED according to some embodiments may be positioned on the ninth interlayer insulating film INS9 in a portion overlapping the light emitting area EA. The light emitting element ED may include a first light emitting element ED1 located in the first light emitting area EA1, a second light emitting element ED2 located in the second light emitting area EA2, and a third light emitting element ED3 located in the third light emitting area EA3. The first light emitting element ED1, the second light emitting element ED2, and the third light emitting element ED3 may be spaced apart from each other.

The first light emitting element ED1, the second light emitting element ED2, and the third light emitting element ED3 may emit light of different colors. As an example, the first light emitting element ED1 may emit red light, the second light emitting element ED2 may emit green light, and the third light emitting element ED3 may emit blue light.

The light emitting element ED may include a connection electrode ANC, a reflective electrode RL, an anode electrode AND, a light emitting layer EL and a cathode electrode CE. Each of the first light emitting element ED1, the second light emitting element ED2, and the third light emitting element ED3 may be distinguished by including the first light emitting layer EL1, the second light emitting layer EL2, and the third light emitting layer EL3 that emit light of different colors. As an example, the first light emitting element ED1 may include a connection electrode ANC, a reflective electrode RL, an anode electrode AND, a first light emitting layer EL1, and a cathode electrode CE, the second light emitting element ED2 may include a connection electrode ANC, a reflective electrode RL, an anode electrode AND, a second light emitting layer EL2, and a cathode electrode CE, and the third light emitting element ED3 may include a connection electrode ANC, a reflective electrode RL, an anode electrode AND, a third light emitting layer EL3, and a cathode electrode CE.

The connection electrode ANC according to some embodiments may be positioned on the ninth interlayer insulating film INS9. The connection electrode ANC may electrically connect the anode electrode AE and the eighth metal layer ML8. The connection electrodes ANC positioned in the portions overlapping each of the first light emitting area EA1, the second light emitting area EA2, and the third light emitting area EA3 may be spaced apart from each other with a pixel defining layer PDL interposed therebetween.

The connection electrode ANC may be formed of an alloy including at least one of copper (Cu), aluminum (Al), tungsten (W), molybdenum (Mo), chromium (Cr), gold (Au), titanium (Ti), nickel (Ni), or neodymium (Nd), or transparent conductive oxide. For example, the connection electrode ANC may include titanium (Ti), titanium nitride (TiN), indium tin oxide (ITO), or indium zinc oxide (IZO), but the embodiments of the present disclosure are not limited thereto.

The reflective electrode RL according to some embodiments may be positioned on the connection electrode ANC. The reflective electrode RL may reflect light emitted from the light emitting layer EL or light incident from the outside. The reflective electrodes RL positioned in the portions overlapping each of the first light emitting area EA1, the second light emitting area EA2, and the third light emitting area EA3 may be spaced apart from each other with a pixel defining layer PDL interposed therebetween.

The reflective electrode RL may be formed of at least one of copper (Cu), aluminum (Al), tungsten (W), molybdenum (Mo), chromium (Cr), gold (Au), titanium (Ti), nickel (Ni), or neodymium (Nd), or an alloy including any one thereof. For example, each of the reflective electrodes RL may include aluminum (Al) having high reflectance.

The anode electrode AND according to some embodiments may be positioned on the reflective electrode RL. The anode electrode AND may be connected to the drain area DRA or the source area SA of the pixel transistor PTR through the reflective electrode RL, the connection electrode ANC, the first to ninth vias VA1 to VA9, the first to eighth conductive layers ML1 to ML8, and the contact terminal CTE. The anode electrodes AND positioned in the portions overlapping each of the first light emitting area EA1, the second light emitting area EA2, and the third light emitting area EA3 may be spaced apart from each other with a pixel defining layer PDL interposed therebetween.

The anode electrode AND may be formed of at least one of copper (Cu), aluminum (Al), tungsten (W), molybdenum (Mo), chromium (Cr), gold (Au), titanium (Ti), nickel (Ni), or neodymium (Nd), an alloy including any one thereof, or transparent conductive oxide. For example, the anode electrode AND may include titanium nitride (TiN), indium tin oxide (ITO), or indium zinc oxide (IZO), but the embodiments of the present disclosure are not limited thereto.

The light emitting layer EL according to some embodiments may be positioned on the anode electrode AE. The light emitting layer EL may be an organic light emitting layer made of an organic material. The light emitting layer EL may be in contact with the anode electrode AE at a portion overlapping an opening OP.

The light emitting layer EL may include a first light emitting layer EL1, a second light emitting layer EL2, and a third light emitting layer EL3. The first light emitting layer EL1 may be positioned in a portion overlapping the first light emitting area EA1, the second light emitting layer EL2 may be positioned in a portion overlapping the second light emitting area EA2, and the third light emitting layer EL3 may be positioned in a portion overlapping the third light emitting area EA3.

The first light emitting layer EL1, the second light emitting layer EL2, and the third light emitting layer EL3 may emit light of different colors. As an example, the first light emitting layer EL1 may emit red light, the second light emitting layer EL2 may emit green light, and the third light emitting layer EL3 may emit blue light, but the present disclosure is not limited thereto.

The side passivation layer SPL according to some embodiments may be positioned on the ninth interlayer insulating film INS9 in a portion overlapping the light emitting area EA. The side passivation layer SPL may be positioned on the light emitting element ED in a direction toward the non-light emitting area NLA. The side passivation layer SPL may expose the opening OP and surround the light emitting element ED. The side passivation layers SPL positioned in the portions overlapping each of the first light emitting area EA1, the second light emitting area EA2, and the third light emitting area EA3 may be spaced apart from each other with a pixel defining layer PDL interposed therebetween.

The side passivation layer SPL may cover the connection electrode ANC, the reflective electrode RL, the anode electrode AND, and the light emitting layer EL included in the light emitting element ED in the direction toward the non-light emitting area NLA. In addition, the side passivation layer SPL may be in contact with the connection electrode ANC, the reflective electrode RL, the anode electrode AND, and the light emitting layer EL.

The side passivation layer SPL may protect the light emitting element ED from moisture permeation from the outside. As a result, the display panel 410 according to some embodiments may provide a display device with relatively improved moisture permeation reliability. A detailed structure of the side passivation layer SPL will be described later.

The side reflective metal SRM according to some embodiments may be positioned on the ninth interlayer insulating film INS9 in a portion overlapping the light emitting area EA. The side reflective metal SRM may be positioned on the side passivation layer SPL in the direction toward the non-light emitting area NLA. In addition, the side reflective metal SRM may expose the opening OP and surround the light emitting element ED. The side reflective metals SRM positioned in the portions overlapping each of the first light emitting area EA1, the second light emitting area EA2, and the third light emitting area EA3 may be spaced apart from each other with a pixel defining layer PDL interposed therebetween.

The side reflective metal SRM may cover the connection electrode ANC, the reflective electrode RL, the anode electrode AND, and the light emitting layer EL included in the light emitting element ED in the direction toward the non-light emitting area NLA.

The side reflective metal SRM can reflect light emitted from the light emitting element ED so as not to be lost. As a result, the display panel 410 according to some embodiments may provide a display device with relatively improved light efficiency. A detailed structure of the side reflective metal SRM will be described later.

The pixel defining layer PDL according to some embodiments may be positioned on the ninth interlayer insulating film INS9 in a portion overlapping the non-light emitting area NLA. The pixel defining layer PDL may partition the first light emitting area EA1, the second light emitting area EA2, and the third light emitting area EA3. The pixel defining layer PDL may define the opening OP and be positioned to surround the opening OP. The pixel defining layer PDL may expose the light emitting layer EL in a portion overlapping the opening OP.

The pixel defining layer PDL may entirely cover the side passivation layer SPL and the side reflective metal SRM in a portion that does not overlap the opening OP. Therefore, the side reflective metals SRM positioned in the portions overlapping each of the first light emitting area EA1, the second light emitting area EA2, and the third light emitting area EA3 may be insulated from each other. In addition, the side reflective metal SRM and the cathode electrode CE positioned in the portions overlapping each of the first light emitting area EA1, the second light emitting area EA2, and the third light emitting area EA3 may be insulated from each other.

The pixel defining layer PDL may include an inorganic insulating material. As an example, the pixel defining layer PDL may include at least one of silicon nitride, silicon oxide, or silicon oxynitride. The pixel defining layer PDL may be formed as a single layer or as a plurality of layers.

The cathode electrode CE according to some embodiments may be positioned on the light emitting layer EL. The cathode electrode CE may be a common electrode. Therefore, the cathode electrode CE may entirely cover each of the first light emitting layer EL1, the second light emitting layer EL2, and the third light emitting layer EL3. In other words, the cathode electrode CE may entirely cover the light emitting layer EL and the pixel defining layer PDL in portions overlapping the light emitting area EA and the non-light emitting area NLA.

The cathode electrode CE may receive a common voltage or a low potential voltage. For example, when the anode electrode AE receives a voltage corresponding to the data voltage and the cathode electrode CE receives the low potential voltage, the light emitting layer EL may emit light as a potential difference is formed between the anode electrode AE and the cathode electrode CE.

The cathode electrode CE may include a transparent conductive material. As an example, the cathode electrode CE may include a material layer having a small work function, such as Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg, etc.).

The cathode electrode CE may further include a transparent metal oxide layer located on the material layer having the small work function.

The passivation layer PVL according to some embodiments may be positioned on the cathode electrode CE. The passivation layer PVL may entirely cover the cathode electrode CE in the portions overlapping the light emitting area EA and the non-light emitting area NLA. The passivation layer PVL may include at least one inorganic insulating material to protect the light emitting element ED from moisture and oxygen entering from the outside. A detailed structure of the passivation layer PVL will be described later.

The optical layer OPL according to some embodiments may be positioned on the light emitting element layer EML. The optical layer OPL may include a plurality of micro lenses LNS and a lens passivation layer LPL covering each micro lens LNS.

The micro lens according to some embodiments may be positioned on the passivation layer PVL in the portion overlapping the light emitting area EA. Each micro lens LNS positioned in the portions overlapping the first light emitting area EA1, the second light emitting area EA2, and the third light emitting area EA3 may be spaced apart from each other. The micro lenses LNS positioned in the portions overlapping each of the first light emitting area EA1, the second light emitting area EA2, and the third light emitting area EA3 may be aligned and positioned with each of the first light emitting element ED1, the second light emitting element ED2, and the third light emitting element ED3.

The lens passivation layer LPL according to some embodiments may be positioned on the micro lens LNS and may entirely cover the micro lens LNS. The lens passivation layer LPL may include at least one inorganic insulating material to protect the light emitting element layer EML from moisture and oxygen entering from the outside. A detailed structure of the lens passivation layer LPL will be described later.

The filling layer FIL according to some embodiments may be positioned on the optical layer OPL. The filling layer FIL may planarize steps between the plurality of micro lenses LNS and the passivation layer PVL. The filling layer FIL may have a refractive index (e.g., a set or predetermined refractive index) to minimize or reduce loss of light.

The filling layer FIL may include an organic material. As an example, the filling layer FIL may include an acrylic resin, an epoxy resin, a phenol resin, and a polyamide resin.

The cover layer CVL according to some embodiments may be positioned on the filling layer FIL. The cover layer CVL may be a glass substrate or a polymer resin such as resin. When the cover layer CVL is a glass substrate, the cover layer CVL may serve as an encapsulation substrate, and when the cover layer CVL is a polymer resin such as resin, an adhesive layer may be added between the cover layer CVL and the filling layer FIL. According to some embodiments, the cover layer CVL may be omitted.

The optical film POL according to some embodiments may be positioned on the cover layer CVL. The optical film POL may be a structure for preventing or reducing deterioration in visibility due to reflection of external light. The optical film POL may include a linear polarizing plate and a phase retardation film. As an example, the phase retardation film may be a λ/4 (quarter-wave) plate, but the embodiments of the present disclosure are not limited thereto.

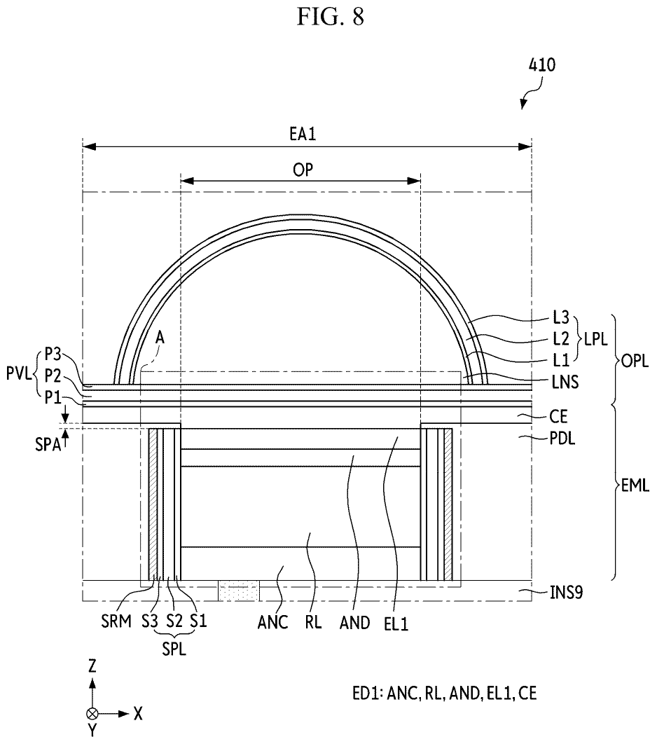

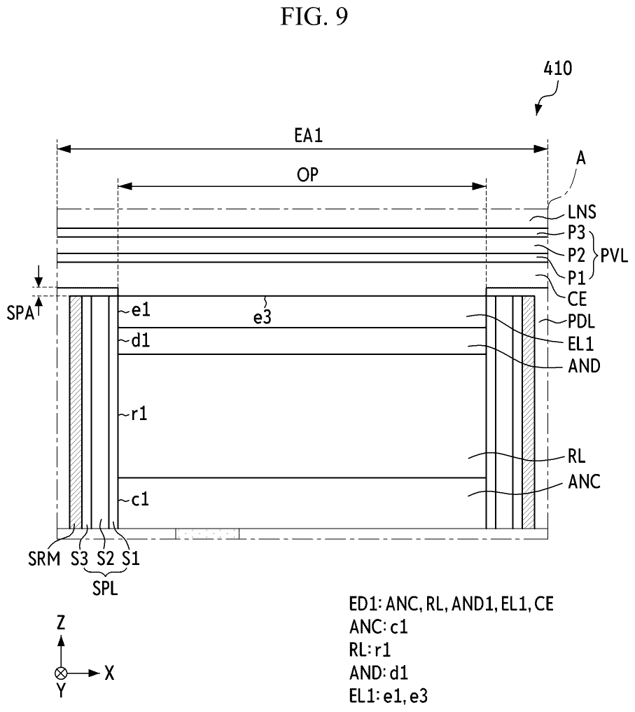

FIG. 8 is an enlarged cross-sectional view of a light emitting element layer and an optical layer positioned to overlap a first light emitting area in FIG. 7. FIG. 9 is an enlarged cross-sectional view of area A of FIG. 8.

Referring to FIGS. 8 and 9, in a portion overlapping the first light emitting area EA1, the light emitting element layer EML may include a first light emitting element ED1, a side passivation layer SPL, a side reflective metal SRM, and a passivation layer PVL, and the optical layer OPL may include a micro lens LNS and a lens passivation layer LPL.

In the portion overlapping the first light emitting area EA1, the first light emitting element ED1 may include a connection electrode ANC, a reflective electrode RL, an anode electrode AND, a first light emitting layer EL1, and a cathode electrode CE. The connection electrode ANC, the reflective electrode RL, the anode electrode AND, the first light emitting layer EL1, and the cathode electrode CE may be sequentially stacked in a portion overlapping the opening OP.

The side passivation layer SPL according to some embodiments may be positioned on a side surface of the first light emitting element ED1. For example, the side passivation layer SPL may be in contact with and cover a side surface c1 of the connection electrode ANC, a side surface r1 of the reflective electrode RL, a side surface d1 of the anode electrode AND, and a side surface e1 of the first light emitting layer EL1. The side passivation layer SPL may not be in contact with an upper surface e3 of the first light emitting layer EL1. In other words, the side passivation layer SPL may not overlap the opening OP.

The side passivation layer SPL may include a plurality of layers. For example, the side passivation layer SPL may include a first layer S1, a second layer S2, and a third layer S3. The first layer S1 of the side passivation layer SPL may be positioned toward the opening OP and be in contact with the light emitting element ED, the third layer S3 thereof may be spaced apart from the first layer S1 in the first direction (X-axis direction) and be in contact with the side reflective metal SRM, and the second layer S2 of the side passivation layer SPL may be positioned in contact between the first layer S1 and the third layer S3.

The side passivation layer SPL may include an inorganic insulating material. However, the first layer S1 and the third layer S3 may include the same material, and the second layer S2 may include a different material from the first layer S1 and the third layer S3. As an example, the first layer S1 and the third layer S3 of the side passivation layer SPL may include silicon oxide, and the second layer S2 thereof may include aluminum oxide.

The first layer S1, the second layer S2, and the third layer S3 of the side passivation layer SPL may be continuously formed in the same process during the manufacturing process. As an example, the first layer S1, the second layer S2, and the third layer S3 may be formed by an Atomic Layer Deposition (ALD) deposition facility. Therefore, it is illustrated in the drawing that the first layer S1, the second layer S2, and the third layer S3 are separated layers, but the first layer S1, the second layer S2, and the third layer S3 may be chemically connected layers. That is, the side passivation layer SPL may have a multi-layer structure in which silicon oxide—aluminum oxide—silicon oxide are chemically connected.

The side reflective metal SRM according to some embodiments may be positioned on the side passivation layer SPL. The side reflective metal SRM may be positioned to be entirely in contact with the third layer S3 of the side passivation layer SPL. The side reflective metal SRM may be in contact with and cover the side surface c1 of the connection electrode ANC, the side surface r1 of the reflective electrode RL, the side surface d1 of the anode electrode AND, and the side surface e1 of the first light emitting layer EL1.

The side reflective metal SRM may include a metal that has good adhesion to an inorganic insulating material and reflective properties. As an example, the side reflective metal SRM may include titanium, platinum, chromium, aluminum, silver, gold, and copper.

The side reflective metal SRM may relatively reduce loss of light emitted from the first light emitting element ED1 by reflecting light that is incident toward the pixel defining layer PDL among the light emitted from the first light emitting element ED1. Therefore, the side reflective metal SRM may increase light efficiency of the display panel 410.

The pixel defining layer PDL according to some embodiments may entirely cover the side passivation layer SPL and the side reflective metal SRM in a portion that does not overlap the opening OP. Therefore, the pixel defining layer PDL may insulate the first light emitting element ED1, the side reflective metal SRM, and the cathode electrode CE. In other words, the cathode electrode CE according to some embodiments may be spaced apart from the side passivation layer SPL and the side reflective metal SRM with a space SPA interposed therebetween in the third direction (Z-axis direction). The space SPA formed between the side passivation layer SPL and the side reflective metal SRM and the cathode electrode CE may be filled by the pixel defining layer PDL.

The passivation layer PVL according to some embodiments may be in contact with and cover the cathode electrode CE. The passivation layer PVL may include a first layer P1, a second layer P2, and a third layer P3 sequentially stacked. The first layer P1 of the passivation layer PVL may be in contact with the cathode electrode CE, the third layer P3 thereof may be spaced apart from the first layer P1 in the third direction (Z-axis direction) and be in contact with the micro lens LNS, and the second layer P2 thereof may be positioned in contact between the first layer P1 and the third layer P3.

The passivation layer PVL may include the same material composition as the side passivation layer SPL. That is, the passivation layer PVL may include an inorganic insulating material. However, the first layer P1 and the third layer P3 may include the same material, and the second layer P2 may include a different material from the first layer P1 and the third layer P3. As an example, the first layer P1 and the third layer P3 of the passivation layer PVL may include silicon oxide, and the second layer P2 thereof may include aluminum oxide.

The first layer P1, the second layer P2, and the third layer P3 of the passivation layer PVL may be continuously formed in the same process during the manufacturing process. As an example, the first layer P1, the second layer P2, and the third layer P3 may be formed by an ALD deposition facility. Therefore, it is illustrated in the drawing that the first layer P1, the second layer P2, and the third layer P3 are separated layers, but the first layer P1, the second layer P2, and the third layer P3 may be chemically connected layers. That is, the passivation layer PVL may have a multi-layer structure in which silicon oxide—aluminum oxide—silicon oxide are chemically connected.

The micro lens LNS according to some embodiments may be positioned in contact with the third layer P3 of the passivation layer PVL. The micro lens LNS may have a cross-sectional shape that is convex in an upward direction, but is not limited thereto.

The micro lens LNS may be a structure that relatively improves the efficiency of light emitted from the first light emitting element ED1. In other words, the micro lens LNS may be a structure for increasing a proportion of light directed toward the front of the display panel 410.

The lens passivation layer LPL according to some embodiments may be in contact with and cover the micro lens LNS. In a portion that does not overlap the micro lens LNS, the lens passivation layer LPL may be in contact with the passivation layer PVL.

The lens passivation layer LPL may include a first layer L1, a second layer L2, and a third layer L3 sequentially stacked. The first layer L1 of the lens passivation layer LPL may be in contact with the micro lens LNS, the third layer L3 thereof may be spaced apart from the first layer L1 in the third direction (Z-axis direction), and the second layer L2 thereof may be positioned in contact between the first layer L1 and the third layer L3.

The lens passivation layer LPL may include the same material composition as the side passivation layer SPL and the passivation layer PVL. That is, the lens passivation layer LPL may include an inorganic insulating material. The first layer L1 and the third layer L3 may include the same material, and the second layer L2 may include a different material from the first layer L1 and the third layer L3. As an example, the first layer L1 and the third layer L3 of the lens passivation layer LPL may include silicon oxide, and the second layer L2 thereof may include aluminum oxide.

The first layer L1, the second layer L2, and the third layer L3 of the lens passivation layer LPL may be continuously formed in the same process during the manufacturing process. As an example, the first layer L1, the second layer L2, and the third layer L3 may be formed by an ALD deposition facility. Therefore, it is illustrated in the drawing that the first layer L1, the second layer L2, and the third layer L3 are separated layers, but the first layer L1, the second layer L2, and the third layer L3 may be chemically connected layers. That is, the lens passivation layer LPL may have a multi-layer structure in which silicon oxide—aluminum oxide—silicon oxide are chemically connected.

As the display panel 410 according to some embodiments includes the side passivation layer SPL, the passivation layer PVL, and the lens passivation layer LPL that protect the first light emitting element ED1, it is possible to protect the first light emitting element ED1 from moisture and moisture entering from the outside.

Therefore, the display panel 410 according to some embodiments may relatively improve reliability.

In addition, as the display panel 410 according to some embodiments includes the side reflective metal SRM and the micro lens LNS that reflect light emitted from the first light emitting element ED1, light efficiency of the display panel 410 may be relatively improved.

For convenience of explanation, the light emitting element layer EML and the optical layer OPL overlapping the first light emitting area EA1 are illustrated and then described, but the light emitting element layer and the optical layer positioned to overlap the second light emitting area EA2 and the third light emitting area EA3 may also have the same structure and characteristics as the structure overlapping the first light emitting area EA1.

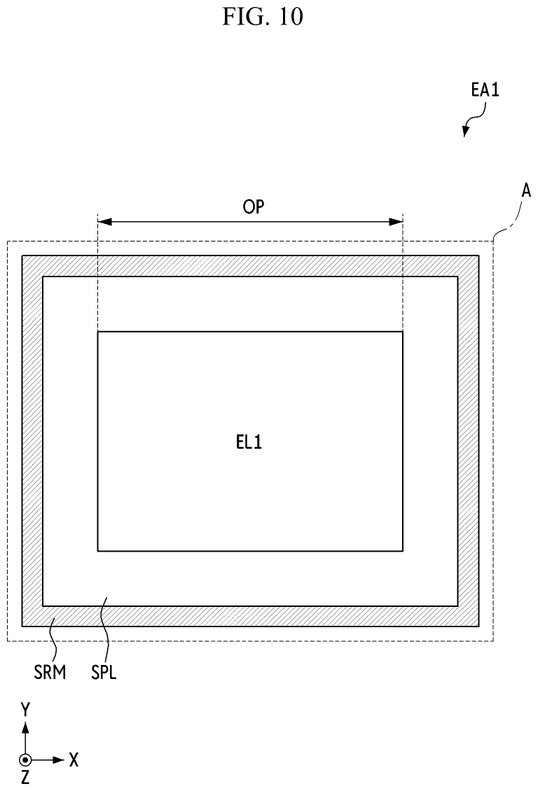

FIG. 10 is a plan view illustrating an arrangement of a first light emitting layer, a side passivation layer, and a side reflective metal in FIG. 9.

Referring to FIG. 10, the side passivation layer SPL may be positioned to surround the opening OP in plan view. In plan view, the side passivation layer SPL may expose the first light emitting layer EL1 in a portion overlapping the opening OP and may be positioned to surround an edge of the first light emitting layer EL1. In other words, in plan view, the first light emitting layer EL1 may be completely surrounded by the side passivation layer SPL.

In plan view, the side reflective metal SRM may completely surround the side passivation layer SPL. In other words, in plan view, the side reflective metal SRM may expose the side passivation layer SPL and the first light emitting layer EL1, and may be positioned to surround the edge of the side passivation layer SPL.

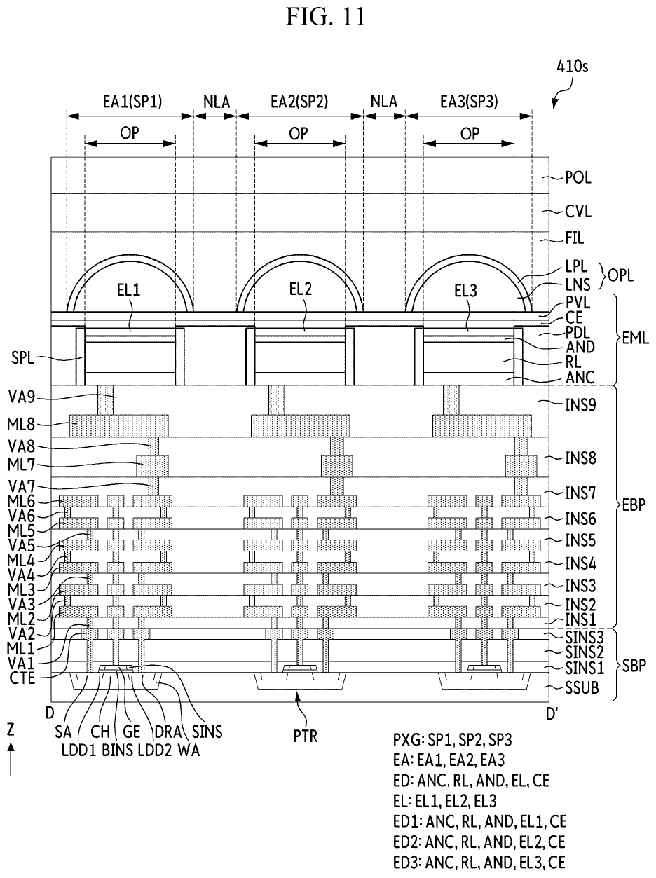

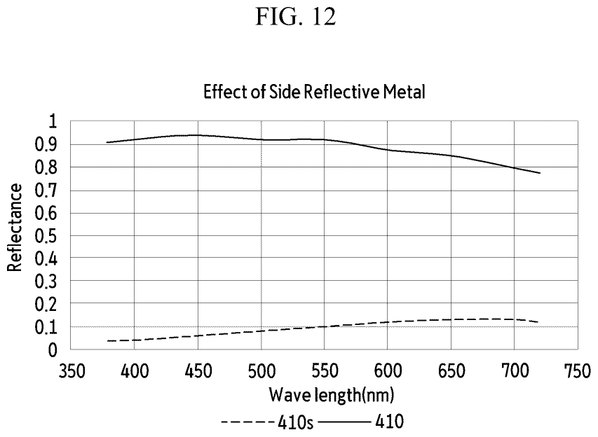

FIG. 11 is a schematic cross-sectional view of the display panel taken along the line D-D′ in FIG. 6 according to some embodiments. FIG. 12 is a graph comparing reflectance of the display panel of FIG. 7 and the display panel of FIG. 11.

Referring to FIGS. 11 and 12, a display panel 410s differs from the display panel 410 in that the display panel 410s does not include the side reflective metal SRM included in the display panel 410. Other structures included in the display panel 410s may be the same as those of the display panel 410. The redundant descriptions will be omitted.

The graph illustrated in FIG. 12 may represent a difference between the reflectance of the display panel 410s and the reflectance of the display panel 410. The reflectance of the display panel 410s and the reflectance of the display panel 410 illustrated in the graph may be data illustrated to include only a difference depending on the presence or absence of the side reflective metal SRM.

The X-axis of the graph represents a wavelength within a visible light range, and the Y-axis of the graph represents the relative reflectance when total reflection is defined as 1.

The reflectance of the display panel 410s indicated by the dotted line may have an average reflectance of 8% (or about 8%) within the visible light range, and the reflectance of the display panel 410 indicated by the solid line may have an average reflectance of 88% (or about 88%) within the visible light range. That is, the reflectance of the display panel 410 may be 80% (or about 80%) higher than the reflectance of the display panel 410s.

In other words, as the display panel 410 includes the side reflective metal (SRM in FIG. 7) covering the side surface of the light emitting element (ED in FIG. 7), the display panel 410 may reflect light emitted from the light emitting element ED, thereby increasing the light efficiency of the display panel 410. The redundant descriptions will be omitted.

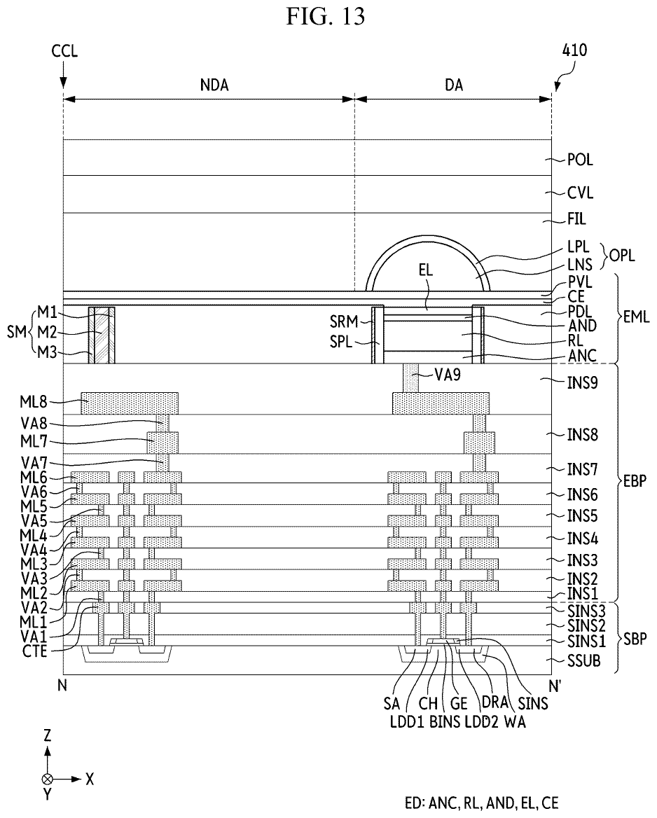

FIG. 13 is a schematic cross-sectional view of the display panel taken along the line N-N′ in FIG. 5.

Referring to FIG. 13, the support metal SM according to some embodiments may be positioned in a portion overlapping the non-display area NDA. The structure of the semiconductor backplane SBP and the light emitting element backplane EBP overlapping the non-display area NDA is only an example and is not limited to the form illustrated.

The support metal SM may be positioned on the ninth interlayer insulating film INS9 in a portion overlapping the non-display area NDA. The support metal SM may be positioned on the same line as the light emitting element ED in the first direction (X-axis direction). In other words, the support metal SM may be positioned on the same line as the side passivation layer SPL and the side reflective metal SRM in the first direction (X-axis direction), and may be spaced apart from the side passivation layer SPL and the side reflective metal SRM in the first direction (X-axis direction). Being positioned on the same line may mean being positioned on the same layer or being positioned to overlap in the first direction (X-axis direction).

The support metal SM can be entirely covered by the pixel defining layer PDL in the portion overlapping the non-display area NDA. In other words, the support metal SM may be completely surrounded by the pixel defining layer PDL and the ninth interlayer insulating film INS9. Therefore, the support metal SM may be insulated from the cathode electrode CE.

The support metal SM may include a plurality of layers. For example, the support metal SM may include a first layer M1, a second layer M2, and a third layer M3. The first layer M1 of the support metal SM may be a portion positioned toward the display area DA and facing the side passivation layer SPL and the side reflective metal SRM, the third layer M3 of the support metal SM may be a portion positioned toward the cell cut line CCL and spaced apart from the first layer M1 in the first direction (X-axis direction), and the second layer M2 of the support metal SM may be a portion positioned in contact between the first layer M1 and the third layer M3.

The first layer M1 and the third layer M3 of the support metal SM may include different materials from the second layer M2.

The first layer M1 and the third layer M3 of the support metal SM may be a metal having barrier properties. As an example, the first layer M1 and the third layer M3 may include either titanium nitride or tungsten nitride.

In addition, the second layer M2 of the support metal SM may be a metal pillar and may include either titanium or tungsten.

As described above, the support metal SM may relatively reduce the impact applied to the structures overlapping the display area DA when performing the dicing process in the manufacturing process. In addition, the support metal SM may protect the plurality of light emitting elements ED positioned in the display area DA from moisture and oxygen permeating from the outside. Therefore, the display panel 410 according to some embodiments may provide a display device with relatively improved mechanical reliability and relatively improved moisture permeation reliability. The redundant descriptions of other structures overlapping the display area DA are omitted.

The display device according to one embodiment of the present disclosure can be applied to various electronic devices. The electronic device according to the one embodiment of the present disclosure includes the display device described above, and may further include modules or devices having additional functions in addition to the display device.

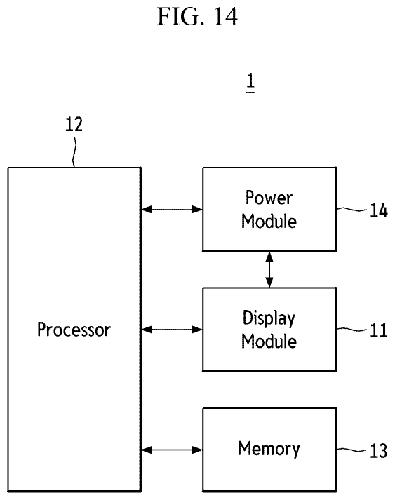

FIG. 14 is a block diagram of an electronic device according to one embodiment of the present disclosure.

Referring to FIG. 14, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

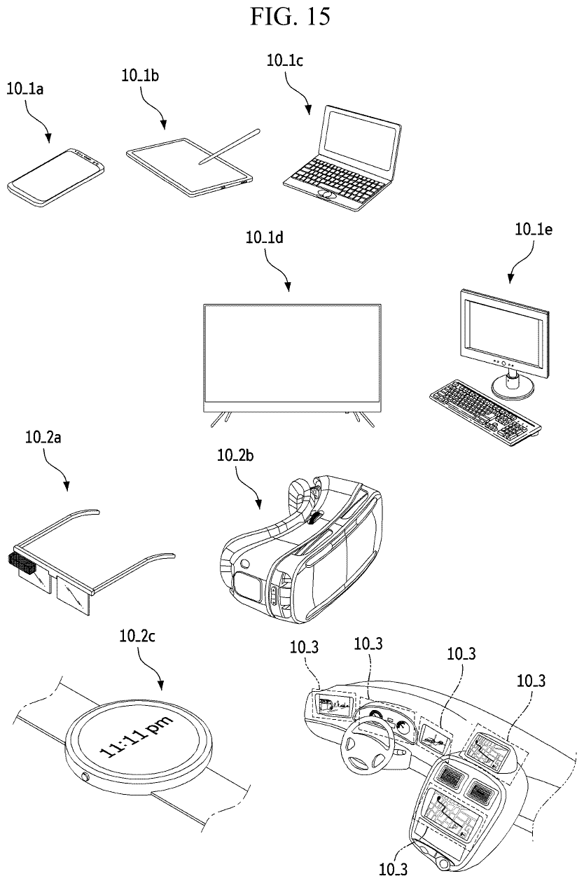

FIG. 15 is a schematic diagram of an electronic device according to various embodiments of the present disclosure.

Referring to FIG. 15, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Although the embodiments of the present disclosure have been described with reference to the accompanying drawings, it will be apparent to those skilled in the art that the present disclosure can be embodied in other specific forms without departing from the technical spirits and essential characteristics. Thus, the above embodiments are to be considered in all respects as illustrative and not restrictive.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it should be understood that the embodiments described above are illustrative in all aspects and not restrictive.

Features of various embodiments of the disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without departing from the spirit and scope of embodiments according to the present disclosure. Therefore, the disclosed embodiments of the invention are used in a generic and descriptive sense and not for purposes of limitation.

What is claimed is:

1. A display device comprising:
a substrate including a display area including a light emitting area and a non-light emitting area and a non-display area surrounding the display area;
a light emitting element on the light emitting area of the substrate;
a side passivation layer on the light emitting element in a direction toward the non-light emitting area;
a side reflective metal on the side passivation layer in a direction toward the non-light emitting area;
a pixel defining layer on the non-light emitting area of the substrate and defining an opening;
a micro lens on the light emitting element; and
a support metal on the non-display area of the substrate and surrounding the display area,
wherein the support metal overlaps the side passivation layer and the side reflective metal in a direction parallel to the substrate, and
the pixel defining layer is in contact with and covers the side passivation layer, the side reflective metal, and the support metal.

2. The display device of claim 1, wherein the side passivation layer and the side reflective metal overlap the light emitting area, and do not overlap the opening, and
wherein the support metal does not overlap the display area, and
the support metal overlaps the light emitting element in the direction parallel to the substrate.

3. The display device of claim 2, wherein the support metal includes:
a first layer facing the display area;
a second layer on the first layer toward an outermost portion of the substrate and including a material different from that of the first layer; and
a third layer on the second layer toward the outermost portion of the substrate and including a same material as the first layer.

4. The display device of claim 3, wherein the first layer and the third layer of the support metal include either titanium nitride or tungsten nitride, and
the second layer includes either titanium or tungsten.

5. The display device of claim 1, wherein the side passivation layer includes:
a first layer in contact with the light emitting element;
a second layer on the first layer and including a material different from that of the first layer; and
a third layer on the second layer and in contact with the side reflective metal.

6. The display device of claim 5, wherein the light emitting element includes an anode electrode, a light emitting layer, and a cathode electrode, and
the first layer contacts and covers a side surface of the anode electrode and a side surface of the light emitting layer facing the non-light emitting area, and
wherein the first layer does not contact an upper surface of the light emitting layer facing the cathode electrode.

7. The display device of claim 6, wherein the light emitting element further includes a connection electrode positioned toward the substrate and a reflective electrode positioned between the connection electrode and the anode electrode, and
the first layer contacts and covers a side surface of the connection electrode and a side surface of the reflective electrode facing the non-light emitting area.

8. The display device of claim 6, wherein the side passivation layer and the side reflective metal are spaced apart from each other with the cathode electrode and the pixel defining layer interposed therebetween in a direction perpendicular to the substrate.

9. The display device of claim 6, wherein in a plan view, the side passivation layer completely surrounds the light emitting layer, and
in the plan view, the side reflective layer completely surrounds the side passivation layer.

10. The display device of claim 1, further comprising:
a passivation layer on the pixel defining layer in a portion overlapping the light emitting area and the non-light emitting area; and
a lens passivation layer on the micro lens.

11. The display device of claim 10, wherein the passivation layer includes:
a first layer contacting the light emitting element;
a second layer on the first layer and including a material different from that of the first layer; and
a third layer on the second layer, contacting the micro lens, and including a same material as the first layer.

12. The display device of claim 11, wherein the first layer, the second layer, and the third layer of the passivation layer overlap the side passivation layer and the side reflective metal in a direction perpendicular to the substrate.

13. The display device of claim 10, wherein the micro lens is in contact between the passivation layer and the lens passivation layer, and
the passivation layer and the lens passivation layer contact each other in a portion that does not overlap the micro lens.

14. The display device of claim 13, wherein the lens passivation layer includes:
a first layer contacting the micro lens;
a second layer on the first layer and including a material different from that of the first layer; and
a third layer on the second layer and including a same material as the first layer.

15. The display device of claim 14, wherein the first layer, the second layer, and the third layer of the lens passivation layer overlap the side passivation layer and the side reflective metal in a direction perpendicular to the substrate.

16. An electronic device comprising at least one display device which comprises a substrate comprising a display area including a light emitting area and a non-light emitting area and a non-display area surrounding the display area;
a light emitting element on the light emitting area of the substrate;
a side passivation layer on the light emitting element in a direction toward the non-light emitting area;
a side reflective metal on the side passivation layer in a direction toward the non-light emitting area;
a pixel defining layer on the non-light emitting area of the substrate and defining an opening;
a micro lens on the light emitting element; and
a support metal on the non-display area of the substrate and positioned to surround the display area,
wherein the support metal overlaps the side passivation layer and the side reflective metal in a direction parallel to the substrate, and
the pixel defining layer contacts and covers the side passivation layer, the side reflective metal, and the support metal.

17. The electronic device of claim 16, wherein the side passivation layer and the side reflective metal overlap the light emitting area, and do not overlap the opening, and
wherein the support metal does not overlap the display area, and
the support metal overlaps the light emitting element in the direction parallel to the substrate.

18. The electronic device of claim 17, wherein the support metal includes:
a first layer facing the display area;
a second layer on the first layer toward an outermost portion of the substrate and including a material different from that of the first layer; and
a third layer on the second layer toward the outermost portion of the substrate and including a same material as the first layer.

19. The electronic device of claim 18, wherein the first layer and the third layer of the support metal include either titanium nitride or tungsten nitride, and
the second layer includes either titanium or tungsten.

20. The electronic device of claim 19, wherein the side passivation layer includes:
a first layer in contact with the light emitting element;
a second layer on the first layer and including a material different from that of the first layer; and
a third layer on the second layer and in contact with the side reflective metal.
